(19) United States
(12) Patent Application Publication
(10) Pub. No.: US 2024/0213311 A1
(43) Pub. Date: Jun. 27, 2024

(54) SILICON CARBIDE SEMICONDUCTOR DEVICE

(71) Applicant: FUJI ELECTRIC CO., LTD., Kawasaki-shi (JP)

(72) Inventors: Syunki NARITA, Matsumoto-city (JP); Shinsuke HARADA, Tsukuba-city (JP)

(73) Assignee: FUJI ELECTRIC CO., LTD., Kawasaki-shi (JP)

(21) Appl. No.: 18/497,333

(22) Filed: Oct. 30, 2023

(30) Foreign Application Priority Data
Nov. 17, 2022 (JP) 2022-184487

(51) Int. Cl. H01L 29/06; H01L 29/16; H01L 29/78

(52) U.S. Cl. CPC H01L 29/0634; H01L 29/1608; H01L 29/7811; H01L 29/7813

(57) ABSTRACT

In an active region and an edge termination region, a drift layer is constituted by a same SJ structure with a parallel pn layer. In the edge termination region, a p⁺-type extension portion between the active region and a JTE structure fixes the JTE structure to the potential of a source electrode. The p⁺-type extension portion is between and in contact with a p-type base extension portion and the parallel pn layer. The p⁺-type extension portion is an extension of upper portions of p⁺-type regions provided in the active region to mitigate electric field near bottoms of gate trenches. Between the p-type base extension portion and the parallel pn layer is free of the lower portions of the p⁺-type regions. Thus, a length in the depth direction of the p-type column regions of the edge termination region is longer than that of the p-type column regions of the active region.

### FIELD OF THE INVENTION

Embodiments of the invention relate to a silicon carbide semiconductor device.

### BACKGROUND TECHNOLOGY

Metal oxide semiconductor field effect transistors (MOSFETs) having insulated gates with a metal-oxide-semiconductor three-layered structure and further having a super junction (SJ) structure in which a drift layer is constituted by a parallel pn layer formed by n-type regions and p-type regions disposed repeatedly alternating with one another in a direction parallel to a main surface of a semiconductor substrate (semiconductor chip) are known.

The drift layer is constituted by the SJ structure, whereby as compared to a normal the drift layer constituted by only an n⁻-type region, an impurity concentration of the drift layer can be increased and on-resistance is significantly reduced. Further, the drift layer is constituted by the SJ structure, whereby increases in the on-resistance during high-temperature operation is suppressed. During high-temperature operation means a semiconductor device operates in a state in which the semiconductor substrate (semiconductor chip) is at a high temperature due to being under a high-temperature environment, application of high voltage, conduction (energization) by a large current, etc.

A voltage withstand structure of a power semiconductor device is configured by multiple p-type regions selectively provided in the semiconductor substrate, at the surface thereof, in an edge termination region between an active region and an end of the semiconductor substrate. In a SiC-MOSFET, as the voltage withstand structure, use of a double-zone junction termination extension (JTE) structure configured by two p-type regions of differing impurity concentrations is known.

FIG. 11 is a plan view depicting a layout when a conventional silicon carbide semiconductor device is viewed from a front side of a semiconductor substrate thereof. FIG. 12 is a cross-sectional view depicting a structure along cutting line AA-AA′ in FIG. 11. FIG. 13 is a plan view depicting a layout when an inner peripheral portion of the edge termination region in FIG. 12 is viewed from a front side of the semiconductor substrate. FIG. 14 is an enlarged plan view depicting a region inside a rectangular frame BB in FIG. 13. FIG. 14 depicts a layout of a p⁺-type extension portion 111a in a linear portion of a semiconductor substrate 140.

FIGS. 15 and 16 are each an enlarged plan view depicting a region inside a rectangular frame CC-CC′ in FIG. 11. FIGS. 15 and 16 each depict a layout of the p⁺-type extension portion 111a and a p⁺-type extension portion 114a in a corner (chip corner) of the semiconductor substrate 140. In FIG. 11, p-type column regions 132 are indicated by hatching. In FIGS. 12 and 13, an inner periphery (inner periphery of a p⁻-type region 122) 124a of a JTE structure is indicated by a dashed line. In FIG. 12, the number of n-type column regions 131 and the number of the p-type column regions 132 depicted are simplified and differ from that depicted in FIG. 16.

In FIGS. 13 and 14, gate trenches 107 are indicated by dashed lines. In FIGS. 14 and 15, p⁺-type regions 111, lower portions 113 of p⁺-type regions 112, the p⁺-type extension portion 111a, and lower portions 115 of p⁺-type connecting portions are indicated by a same hatching. In FIG. 16, upper portions 114 of p⁺-type regions 112, the p⁺-type extension portion 114a, and upper portions 116 of the p⁺-type connecting portions are indicated by a same hatching. In FIGS. 15 and 16, the gate trenches 107 are indicated by bold lines and an inner periphery 124a of a JTE structure 121 are indicated by dashed lines. Reference character 124b is an outer periphery of the JTE structure 121 (outer periphery of a p⁻-type region 123).

A conventional silicon carbide semiconductor device 150 depicted in FIGS. 11 to 16 is a trench gate SiC-MOSFET having the SJ structure with a parallel pn layer 103 constituting the drift layer and provided in the semiconductor substrate 140 that contains silicon carbide (SiC) as a semiconductor material. The semiconductor substrate 140 is formed by sequentially forming, on an n⁺-type starting substrate 141 containing SiC as a semiconductor material, epitaxial layers 142, 143 by epitaxial growth; the epitaxial layers 142, 143 constitute the parallel pn layer 103 and a p-type base region 104.

The parallel pn layer 103 is formed by disposing n-type regions (hereinafter, n-type column regions) 131 and p-type regions (hereinafter, p-type column regions) 132 to repeatedly alternate with one another in a first direction X parallel to a main surface of the semiconductor substrate 140. The n-type column regions 131 and the p-type column regions 132, in an entire area of the semiconductor substrate 140, extend in a striped pattern in a second direction Y parallel to a main surface of the semiconductor substrate 140 and orthogonal to the first direction X.

In both an active region 110 and an edge termination region 120, the drift layer is configured by a same SJ structure. Both the n-type column regions 131 and the p-type column regions 132, have substantially a same width (width in a lateral direction) Wn101, Wp101 and substantially a same impurity concentration. Substantially the same width and substantially the same impurity concentration mean, respectively, the same width and the same impurity concentration within respective ranges that include allowable error due to manufacturing process variation.

In the active region 110 and the edge termination region 120, balanced charge is generally maintained between any one of the n-type column regions 131 and an adjacent one thereto of the p-type column regions 132. Charge balance is an indicator of the degree of equilibrium between the amount of charge expressed as a product of carrier concentration (impurity concentration) of the n-type column regions 131 and the width Wn101, and the amount of charge expressed as a product of carrier concentration of the p-type column regions 132 and the width Wp101.

In the active region 110, between front surface (main surface having the p-type epitaxial layer 143) of the semiconductor substrate 140 and the parallel pn layer 103, a trench gate structure is provided. The trench gate structure is configured by n⁺-type source regions 105, p⁺⁺-type contact regions 106, the gate trenches 107, the gate insulating films 108, and gate electrodes 109. At deep positions closer to an n⁺-type drain region 101 than are bottoms of the gate trenches 107, the p⁺-type regions 111, 112 are selectively provided.

The p⁺-type regions 111, 112 have a function of mitigating electric field applied to the gate insulating films 108 at the bottoms of the gate trenches 107. The p⁺-type regions 111 are provided apart from the p-type base region 104 and face the bottoms of the gate trenches 107, respectively. Between any adjacent two of the gate trenches 107, the p⁺-type regions 112 are provided in contact with the p-type base region 104 but apart from the p⁺-type regions 111 and the gate trenches 107.

The p⁺-type regions 112 are diffused regions on the parallel pn layer 103, each configured by one of the lower portions (portions facing the n⁺-type drain region 101) 113 and one of the upper portions (portions facing the n⁺-type source regions 105) 114 adjacent to each other in a depth direction Z and formed by performing ion implantation of a p-type impurity in each layer formed at each stage into which epitaxial growth of the n-type epitaxial layer 142 constituting the drift layer is divided, herein, two stages (two sessions). The p⁺-type regions 111 are formed concurrently with the lower portions 113 of the p⁺-type regions 112.

The edge termination region 120 surrounds a periphery of the active region 110. An outer (relatively closer to or facing an end of the semiconductor substrate 140 (end side): chip end side) portion of the p-type epitaxial layer 143 is removed and in the edge termination region 120, an incline 144 is formed at the front surface of the semiconductor substrate 140. The front surface of the semiconductor substrate 140 includes a first portion 140a and a second portion 140b separated by the incline 144, the first portion 140a being on a chip center (a center of the semiconductor substrate 140) side of the incline 144 and the second portion 140b being on the chip end side of the incline 144 and recessed toward a drain electrode 119.

Due to the incline 144, at the front surface of the semiconductor substrate 140, the p-type epitaxial layer 143 remains and has a mesa-like shape (protruding shape) in the chip center. The first portion 140a of the front surface of the semiconductor substrate 140 is a surface the p-type epitaxial layer 143 while the second portion 140b is a surface the n-type epitaxial layer 142, which is exposed by removing the p-type epitaxial layer 143 in the edge termination region 120.

In the edge termination region 120, closer to the chip end than is the incline 144, the JTE structure 121 configured by multiple p-type regions (here, two: the p⁻-type region 122, the p⁻⁻-type region 123) of differing impurity concentrations is provided as a voltage withstand structure. The p⁻-type region 122 and the p⁻⁻-type region 123 are provided between the second portion 140b of the front surface of the semiconductor substrate 140 and the parallel pn layer 103, are in contact with the parallel pn layer 103, and surround the periphery of the active region 110 in concentric shapes.

The parallel pn layer 103 extends closer to the chip end than is the JTE structure 121. A portion between the end of the semiconductor substrate 140 and the parallel pn layer 103 is a normal n-type drift region 133 free of the SJ structure. The second portion 140b of the front surface of the semiconductor substrate 140 is covered by an insulating layer (a single-layer structure of an interlayer insulating film 117 or a stacked structure in which a field oxide film (not depicted) and the interlayer insulating film 117 are sequentially stacked).

Further, in the edge termination region 120, closer to the chip center than is the incline 144, the p⁺-type extension portion 111a, the p⁺-type extension portion 114a, and a p-type base extension portion 104a are provided between the first portion 140a of the front surface of the semiconductor substrate 140 and the parallel pn layer 103. The p⁺-type extension portion 111a, the p⁺-type extension portion 114a, and the p-type base extension portion 104a are extended portions of the p⁺-type regions 111, the upper portions 114 of the p⁺-type regions 112, and the p-type base region 104, respectively.

The p⁺-type extension portions 111a, 114a and the p-type base extension portion 104a extend in the first direction X toward the chip center and reach, of the gate trenches 107, ones closest to the chip end in the first direction X (hereinafter, outermost gate trenches 107a) while in the second direction Y, the p⁺-type extension portions 111a, 114a and the p-type base extension portion 104a reach all the ends of the gate trenches 107 in the longitudinal direction of the gate trenches 107; the p⁺-type extension portions 111a, 114a and the p-type base extension portion 104a further extend toward the chip end and reach a third portion (mesa edge of the incline) 140c of the front surface of the semiconductor substrate 140, the third portion 140c connecting the first portion 140a and the second portion 140b.

The p⁺-type extension portion 111a, the p⁺-type extension portion 114a, and the p-type base extension portion 104a are provided in an entire region from the active region 110 to the incline 144 and surround the periphery of the active region 110 (FIGS. 15 and 16). Of the p⁺-type extension portions 111a, 114a, at least the p⁺-type extension portion 111a has an outer periphery portion 124c thereof reaching closer to the chip end than is the inner periphery 124a of the JTE structure 121, and overlaps an inner peripheral side of the p⁻-type region 122 closest to the chip center, among the regions of the JTE structure 121 (FIGS. 12 and 13).

The JTE structure 121 is in contact with the p⁺-type extension portion 111a provided in an inner peripheral portion 120a of the edge termination region 120 and is fixed to the potential of a source electrode 118 via the p⁺-type extension portions 111a, 114a, and the p-type base extension portion 104a. The p-type column regions 132 of the active region 110 are in contact with the p⁺-type regions 112 and fixed to the potential of the source electrode 118 via the p⁺-type regions 112, the p-type base region 104, and the p⁺⁺-type contact regions 106.

The p-type column regions 132 closer to the chip center than is the JTE structure 121 of the edge termination region 120 are in contact with the p⁺-type extension portion 111a and fixed to the potential of the source electrode 118 via the p⁺-type extension portions 111a, 114a, and the p-type base extension portion 104a. The p-type column regions 132 that are in contact with the JTE structure 121 are fixed to the potential of the source electrode 118 via the JTE structure 121. The p-type column regions 132 closer to the chip end than is the JTE structure 121 are electrically floating.

As for a conventional vertical silicon carbide semiconductor device with a SJ structure, a device has been proposed in which as the p-type column regions of a parallel pn layer, long p-type column regions having a relatively long length from the front surface of the semiconductor substrate to the bottom or short p-type column regions having a relatively short length from the front surface of the semiconductor substrate to the bottom are disposed, in a region where the short p-type column regions are disposed, a charge balance with a large amount of an n-type impurity is assumed, a position where avalanche breakdown occurs is induced at the bottoms of the short p-type column regions, a concentration of current at a channel is eliminated, whereby drops in avalanche breakdown voltage are suppressed (for example, refer to Patent Document 1)

### PRIOR ART LITERATURE

### Patent Literature

Patent Document 1: Japanese Laid-Open Patent Publication No. 2020-191441).

### DISCLOSURE OF INVENTION

### Problem to be Solved by the Invention

As described above, in the SiC-MOSFET with the conventional SJ structure (refer to FIGS. 11 to 16), the drift layer is configured by the same SJ structure (the n-type column regions 131 and the p-type column regions 132) in the active region 110 and in the edge termination region 120. Thus, the breakdown voltage of the edge termination region 120 is lower than the breakdown voltage of the active region 110 and avalanche breakdown easily occurs in the edge termination region 120. As a result, a problem arises in that breakdown tolerance decreases as compared to an instance in which avalanche breakdown occurs in the active region 110, which occupies a majority of the area (surface area) of the semiconductor substrate 140.

To solve the problems associated with the conventional techniques described above, one object of the present invention is to provide a silicon carbide semiconductor device capable of enhancing breakdown tolerance.

### Means for Solving Problem

To solve the problems described above and achieve an object of the present invention, a silicon carbide semiconductor device according to the present invention has the following features. An active region is provided on a semiconductor substrate containing silicon carbide. A termination region surrounds a periphery of the active region. A parallel pn layer is provided in the semiconductor substrate, in the active region and the termination region. The parallel pn layer has first-conductivity-type column regions and second-conductivity-type column regions disposed repeatedly alternating with one another in a first direction parallel to a front surface of the semiconductor substrate. A first semiconductor region of a second conductivity type is provided between the first main surface of the semiconductor substrate and the parallel pn layer, the first semiconductor region extending from the active region to the termination region.

In the active region, second semiconductor regions of the first conductivity type are selectively provided between the first main surface and the first semiconductor region. Trenches penetrate through the second semiconductor regions and the first semiconductor region in a depth direction and reach the first-conductivity-type column regions. In the trenches, gate electrodes are provided via gate insulating films. In the active region and the termination region, second-conductivity-type high-concentration regions are selectively provided between the first semiconductor region and the parallel pn layer. The second-conductivity-type high-concentration regions have an impurity concentration higher than an impurity concentration of the second semiconductor regions.

A voltage withstand structure is selectively provided between the first main surface and the parallel pn layer, closer to an end of the semiconductor substrate than are the first semiconductor region and the second-conductivity-type high-concentration regions, the voltage withstand structure being configured by one or more second-conductivity-type voltage withstanding regions surrounding a periphery of the active region in concentric shapes. A first electrode is electrically connected to the second semiconductor regions, the first semiconductor region, and the second-conductivity-type high-concentration regions. A second electrode is electrically connected to a second main surface of the semiconductor substrate. Of the second-conductivity-type high-concentration regions, a portion in the active region reaches deep positions closer to the second main surface than are bottoms of the trenches and a portion closer to the termination region than is the portion in the active region has a surface that faces the second main surface and is positioned close to the first main surface.

Further, in the silicon carbide semiconductor device according to the present invention, in the invention described above, each of the portion of the second-conductivity-type high-concentration regions in the active region has a first part closer to the second main surface than are the bottoms of the trenches and a second part closer to the first main surface than are the bottoms of the trenches. The portion of the second-conductivity-type high-concentration regions of the termination region is characterized in that the second part extends to the termination region.

Further, the silicon carbide semiconductor device according to the present invention is characterized in that, in the invention described above, the first part of each of the second-conductivity-type high-concentration regions surrounds the periphery of the active region and maintains a predetermined distance relative to outermost peripheral sidewalls of the trenches, the outermost peripheral sidewalls being adjacent to the termination region.

Further, the silicon carbide semiconductor device according to the present invention is characterized in that, in the invention described above, the first part of each of the second-conductivity-type high-concentration regions terminates closer to the end of the semiconductor substrate than are the outermost peripheral sidewalls of the trenches by not more than 0.35 μm, the outermost peripheral sidewalls being adjacent to the termination region.

Further, the silicon carbide semiconductor device according to the present invention is characterized in that, in the invention described above, the first part of each of the second-conductivity-type high-concentration regions surrounds the periphery of the active region, maintaining a predetermined distance relative to an inner periphery of the voltage withstand structure.

Further, the silicon carbide semiconductor device according to the present invention is characterized in that, in the invention described above, the portion of the second-conductivity-type high-concentration regions of the termination region are provided in an entire area between the active region and the voltage withstand structure.

Further, the silicon carbide semiconductor device according to the present invention is characterized in that, in the invention described above, the portion of the second-conductivity-type high-concentration regions of the termination region is selectively provided.

Further, the silicon carbide semiconductor device according to the present invention is characterized in that, in the invention described above, the portion of the second-conductivity-type high-concentration regions of the termination region is provided only between the first semiconductor region and the second-conductivity-type column regions.

Further, in the silicon carbide semiconductor device according to the present invention, in the invention described above, the first-conductivity-type column regions and the second-conductivity-type column regions extend in a stripe pattern in a second direction parallel to the front surface of the semiconductor substrate and orthogonal to the first direction. The portion of the second-conductivity-type high-concentration regions of the termination region is characterized in that said portion is provided in a stripe pattern in the second direction.

Further, in the silicon carbide semiconductor device according to the present invention, in the invention described above, the first-conductivity-type column regions and the second-conductivity-type column regions extend in a stripe pattern in the second direction parallel to the front surface of the semiconductor substrate and orthogonal to the first direction. The portion of the second-conductivity-type high-concentration regions of the termination region is characterized in that said portion is scattered in the second direction so as to be disposed in a matrix-like pattern between the active region and the voltage withstand structure.

Further, the silicon carbide semiconductor device according to the present invention is characterized in that, in the invention described above, each of the portion of the second-conductivity-type high-concentration regions of the termination region has a width in the first direction narrower than a width of each of the second-conductivity-type column regions in the first direction.

According to the present invention described above, the breakdown voltage of the termination region may be enhanced and thus, a location where avalanche breakdown occurs may be changed to the active region, which has a large area occupying a majority of the area (surface area) of the semiconductor substrate.

### Effect of the Invention

The silicon carbide semiconductor device according to the present invention achieves an effect in that breakdown tolerance may be enhanced.

### BRIEF DESCRIPTION OF THE DRAWINGS

FIG. 1 is a plan view depicting a layout when a silicon carbide semiconductor device according to a first embodiment is viewed from a front side of a semiconductor substrate thereof.

FIG. 2 is a cross-sectional view depicting a structure along cutting line A-A′ in FIG. 1.

FIG. 3 is a plan view depicting a layout when an inner peripheral portion of an edge termination region in FIG. 2 is viewed from a front side of the semiconductor substrate.

FIG. 4A1 is an enlarged plan view depicting a region inside a rectangular frame B1 in FIG. 3.

FIG. 4A2 is an enlarged plan view depicting a region inside a rectangular frame B2 in FIG. 4A1.

FIG. 4B is an enlarged plan view depicting a region inside a rectangular frame B1 in FIG. 3.

FIG. 5A is an enlarged plan view depicting a region inside a rectangular frame C1-C1′ in FIG. 1.

FIG. 5B is an enlarged plan view depicting a region inside a rectangular frame C1-C1′ in FIG. 1.

FIG. 6A is an enlarged plan view depicting a region inside a rectangular frame C1-C1′ in FIG. 1.

FIG. 6B is an enlarged plan view depicting a region inside a rectangular frame C1-C1′ in FIG. 1.

FIG. 7 is an enlarged plan view depicting a region inside a rectangular frame C1-C1′ in FIG. 1.

FIG. 8 is a cross-sectional view depicting a structure of a silicon carbide semiconductor device according to a second embodiment.

FIG. 9A is an enlarged plan view depicting a region inside a rectangular frame C1-C1′ in FIG. 1.

FIG. 9B is an enlarged plan view depicting a region inside a rectangular frame C4 in FIG. 9A.

FIG. 10 is a characteristics diagram depicting breakdown voltage characteristics of first and second examples.

FIG. 11 is a plan view depicting a layout when a conventional silicon carbide semiconductor device is viewed from a front side of a semiconductor substrate thereof.

FIG. 12 is a cross-sectional view depicting a structure along cutting line AA-AA′ in FIG. 11.

FIG. 13 is a plan view depicting a layout when an inner peripheral portion of the edge termination region in FIG. 12 is viewed from a front side of the semiconductor substrate.

FIG. 14 is an enlarged plan view depicting a region inside a rectangular frame BB in FIG. 13.

FIG. 15 is an enlarged plan view depicting a region inside a rectangular frame CC-CC′ in FIG. 11.

FIG. 16 is an enlarged plan view depicting a region inside a rectangular frame CC-CC′ in FIG. 11.

### BEST MODE (S) FOR CARRYING OUT THE INVENTION

Embodiments of a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

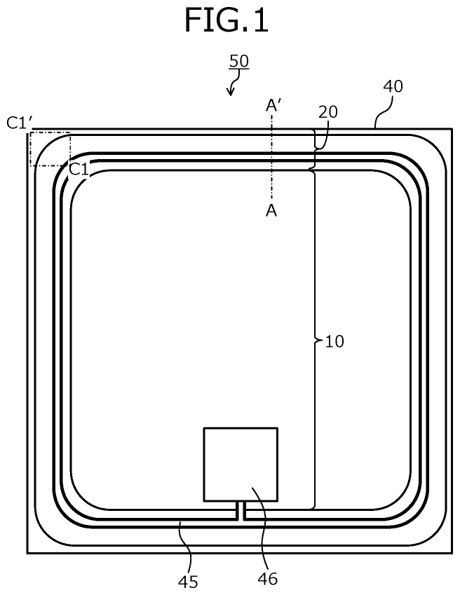

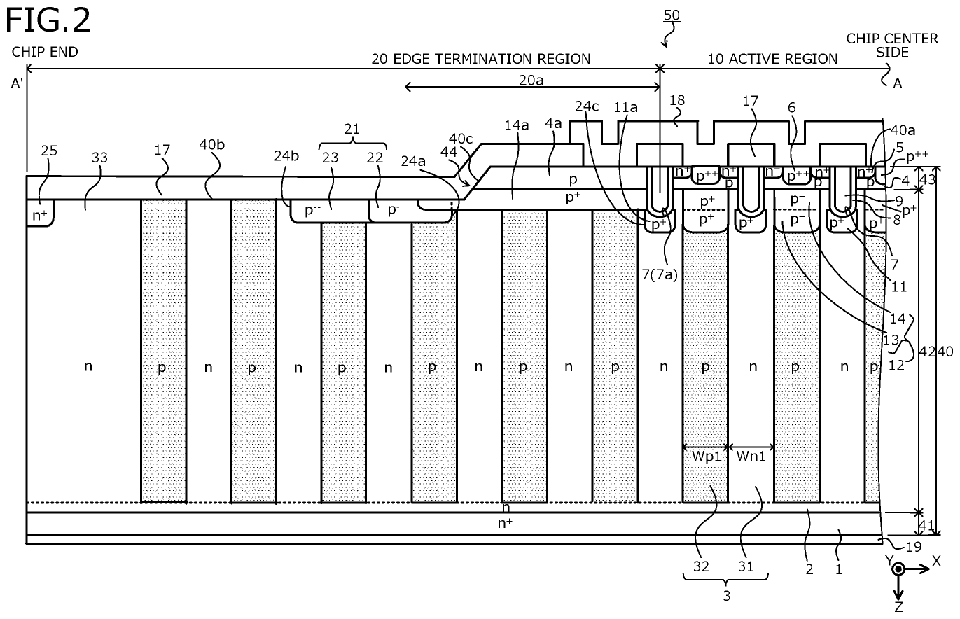

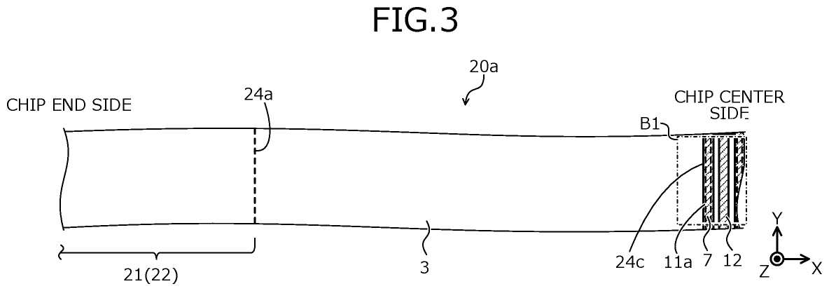

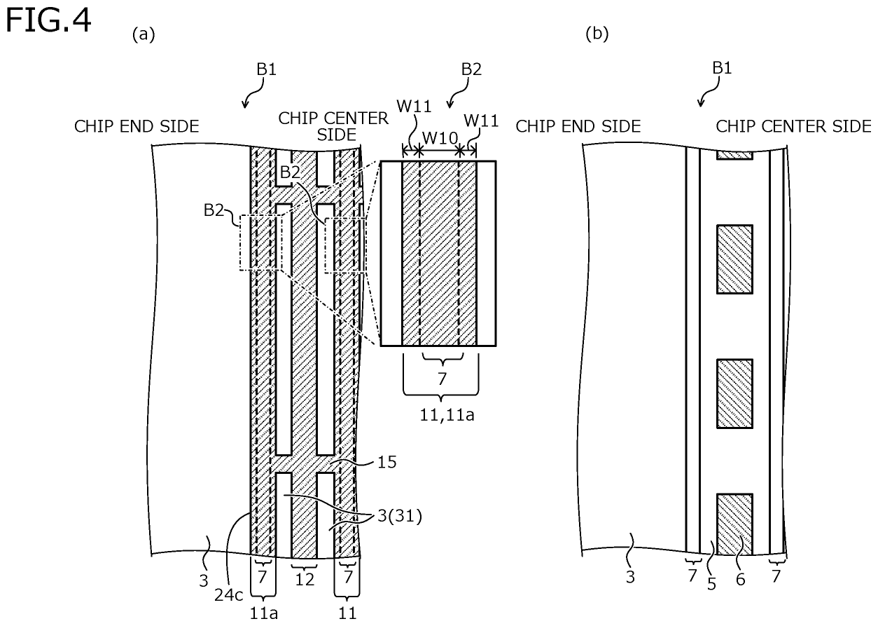

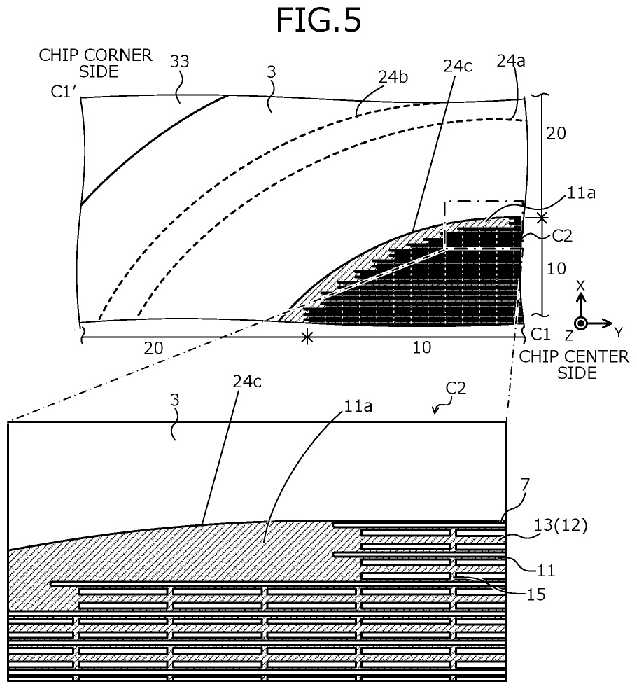

A structure of a silicon carbide semiconductor device according to a first embodiment is described. FIG. 1 is a plan view depicting a layout when the silicon carbide semiconductor device according to the first embodiment is viewed from a front side of a semiconductor substrate thereof. FIG. 2 is a cross-sectional view depicting the structure along cutting line A-A′ in FIG. 1. FIG. 3 is a plan view depicting a layout when an inner peripheral (side facing a chip center) portion of an edge termination region in FIG. 2 is viewed from a front side of the semiconductor substrate. FIGS. 4A1 and 4B are enlarged plan views depicting a region inside a rectangular frame B1 in FIG. 3; FIG. 4A2 is an enlarged plan view depicting a region inside a rectangular frame B2 in FIG. 4A1. FIGS. 5A, 5B, 6A, 6B and 7 are enlarged plan views depicting a region inside a rectangular frame C1-C1′ in FIG. 1.

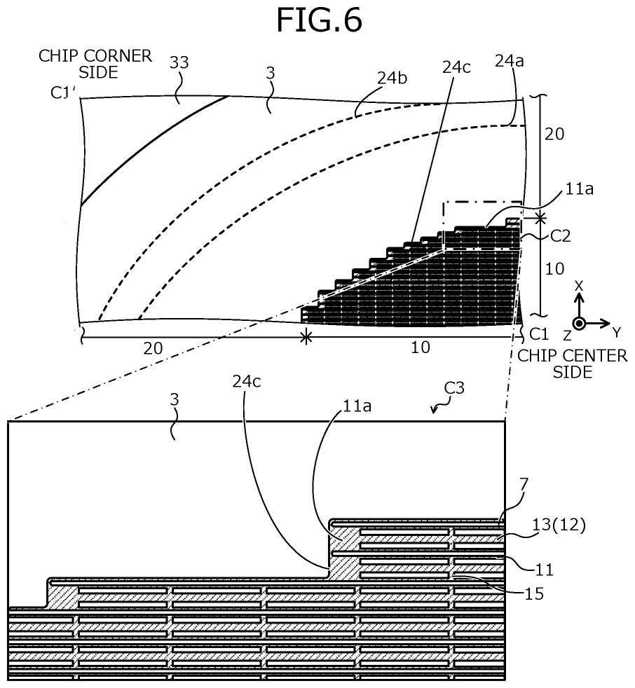

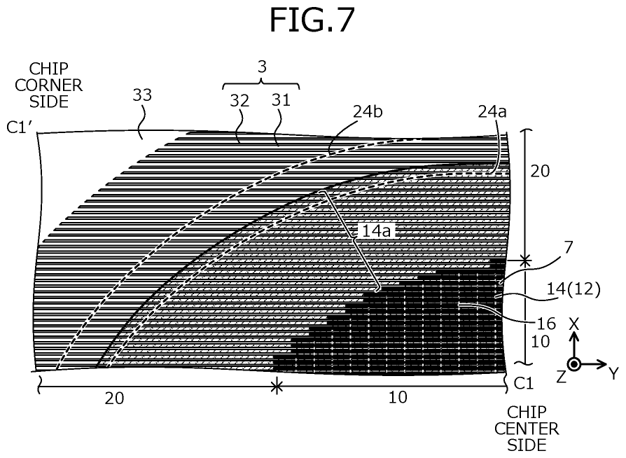

FIGS. 3, 4A1, and 4A2 depict a layout of a p⁺-type region 11a in a linear portion (edge) of a semiconductor substrate 40. FIG. 4B depicts a layout of n⁺-type source regions 5 and p⁺⁺-type contact regions 6. FIGS. 5A, 5B, 6A, and 6B depict an example of layout of the p⁺-type region 11a at a corner (chip corner: vertex) of the semiconductor substrate 40. FIGS. 5A and 6A are enlarged views of a region inside a rectangular frame C1-C1′ in FIG. 1 while FIGS. 5B and 6B are enlarged views of region inside rectangular frames C2, C3 in FIGS. 5A and 6A, respectively. FIG. 7 depicts a layout of a p⁺-type extension portion 14a at a corner of the semiconductor substrate 40.

In FIG. 2, p-type column regions 32 are indicated by hatching. In FIG. 2, a portion of an inner periphery (inner periphery of a p⁻-type region 22) 24a of a JTE structure 21 overlapping the p⁺-type extension portion 14a is indicated by a dashed line, and a gate runner 45 is not depicted. In FIG. 2, the number of n-type column regions 31 and the number of the p-type column regions 32 depicted are simplified and differ from that depicted in FIG. 7. In FIGS. 3 to 6B, the n-type column regions 31 and the p-type column regions 32 are not depicted. In FIG. 3, the inner periphery 24a of the JTE structure 21 is indicated by a dashed line. In FIGS. 3, 4A1, and 4A2, gate trenches 7 are indicated by dashed lines.

In FIG. 4B, the p⁺⁺-type contact regions 6 are indicated by hatching. In FIGS. 4A1, 4A2, 5A, 5B, 6A, and 6B, p⁺-type regions 11, 11a, lower portions 13 of p⁺-type regions 12, and lower portions 15 of the p⁺-type connecting portions are indicated by hatching. In FIGS. 5A, 6A, and 7, the gate trenches 7 are indicated by bold lines while the inner periphery 24^{a} and an outer periphery (outer periphery of a p⁻-type region 23) 24b of the JTE structure 21 are indicated by dashed lines. In FIG. 7, upper portions 14 of the p⁺-type regions 12, the p⁺-type extension portion 14a, and upper portions 16 of the p⁺-type connecting portions are indicated by the same hatching.

A silicon carbide semiconductor device 50 according to the first embodiment depicted in FIGS. 1 to 7 has a trench gate structure (device structure) in the semiconductor substrate (semiconductor chip) 40 containing silicon carbide (SiC), the trench gate structure being provided at a front surface (first main surface) of the semiconductor substrate 40, in an active region 10; and the silicon carbide semiconductor device 50 is a vertical SiC-MOSFET with a SJ structure in which a parallel pn layer 3 constitutes a drift layer (drift region). The active region 10 is a region through which a main current flows when the MOSFET is in an on-state. The active region 10 is disposed in substantially a center (the chip center) of the semiconductor substrate 40.

The active region 10 is a portion farther inward (toward the chip center) than is a center of outermost ones (ones closest to an end of the semiconductor substrate 40, a chip end) of the gate trenches 7 (hereinafter, outermost gate trenches 7a) in the later-described first direction X and farther inward than is an end (not depicted) of the n⁺-type source regions 5 in the later-described second direction Y. In the active region 10, multiple unit cells (constituent units of the device) each having the same structure (the trench gate structure) are disposed adjacent to one another. The trench gate structure, in the active region 10, is provided between the front surface of the semiconductor substrate 40 and the parallel pn layer 3.

An edge termination region 20 is between the active region 10 and the end of the semiconductor substrate 40 (the chip end). The edge termination region 20 surrounds a periphery of the active region 10. The edge termination region 20 has a function of mitigating electric field of the front side of the semiconductor substrate 40 and sustaining a breakdown voltage of the drift layer. The breakdown voltage is a voltage limit at which malfunction and destruction of the device do not occur and leakage current does not excessively increase. In the edge termination region 20, between the front surface of the semiconductor substrate 40 and the parallel pn layer 3, the later-described JTE structure 21 is disposed as a voltage withstand structure.

In the semiconductor substrate 40, on a front surface of an n⁺-type starting substrate 41 containing silicon carbide, epitaxial layers 42, 43 constituting the parallel pn layer 3 and a p-type base region (first semiconductor region) 4 are sequentially stacked. The semiconductor substrate 40 has, as the front surface, a main surface having the p-type epitaxial layer 43 and has, as a back surface (second main surface), a main surface having the n⁺-type starting substrate 41. The n⁺-type starting substrate 41 constitutes an n⁺-type drain region 1. The parallel pn layer 3, for example, is formed on the n⁺-type starting substrate 41 by a later-described multistage epitaxial method, trench-embedding epitaxial method, etc.

The parallel pn layer 3 is formed by disposing the n-type regions (the n-type column regions: first-conductivity-type column regions) 31 and the p-type regions (the p-type column regions: second-conductivity-type column regions) 32 to be adjacent to and repeatedly alternate with one another in the first direction X parallel to a main surface of the semiconductor substrate 40. The n-type column regions 31 and the p-type column regions 32, in substantially an entire area of the semiconductor substrate 40, extend in a striped pattern in the second direction Y parallel to a main surface of the semiconductor substrate 40 and orthogonal to the first direction X. In both the active region 10 and the edge termination region 20, the drift layer is configured by the same SJ structure. Balanced charge is maintained between any one of the n-type column regions 31 and an adjacent one of the p-type column regions 32.

Charge balance is an indicator of the degree of equilibrium between the amount of charge of the n-type column regions 31 expressed as a product of the carrier concentration (impurity concentration) and a width Wn1 of the n-type column regions 31 and the amount of charge of the p-type column regions 32 expressed as a product of the carrier concentration and a width Wp1 of the p-type column regions 32. For example, both the n-type column regions 31 and the p-type column regions 32 have substantially the same width (width in a lateral direction) Wn1, Wp1 and substantially the same impurity concentration. Substantially the same width and substantially the same impurity concentration mean, respectively, the same width and the same impurity concentration within respective ranges that include allowable error due to manufacturing process variation.

A portion of the n-type epitaxial layer 42 between the parallel pn layer 3 and the n⁺-type drain region 1 may be an n-type buffer region (n-type region free of the SJ structure) 2. The n-type buffer region 2 is in contact with the parallel pn layer 3, the n⁺-type drain region 1, and a later-described normal n-type drift region 33 that is free of the SJ structure. An impurity concentration of the n-type buffer region 2 is at most equal to an impurity concentration of the n-type column regions 31. The n-type column regions 31 and the p-type column regions 32 reach the n-type buffer region 2 (in an instance in which the n-type buffer region 2 is omitted, the n⁺-type drain region 1) in the depth direction Z.

The p-type column regions 32 of the active region 10 are in contact with the later-described p⁺-type regions 12 and are fixed to a potential of a source electrode 18, via the p⁺-type regions 12, the p-type base region 4, and the p⁺⁺-type contact regions 6. The p-type column regions 32 of the edge termination region 20 are in contact with the later-described p⁺-type extension portion 14a and are electrically connected to the source electrode 18, via the p⁺-type extension portion 14a and a later-described p-type base extension portion 4a, or via said regions and the JTE structure 21. The p-type column regions 32 that are disposed closer to the chip end than is the JTE structure 21 are electrically floating.

The trench gate structure is formed by the p-type base region 4, the n⁺-type source regions (second semiconductor regions) 5, the p⁺⁺-type contact regions 6, the gate trenches (trenches) 7, gate insulating films 8, and gate electrodes 9. The p-type base region 4 is provided between the front surface of the semiconductor substrate 40 and the parallel pn layer. The p-type base region 4 is a portion of the p-type epitaxial layer 43 excluding the n⁺-type source regions 5 and the p⁺⁺-type contact regions 6. The p-type base region 4 extends outward from the active region 10 to a later-described incline 44.

The n⁺-type source regions 5 and the p⁺⁺-type contact regions 6 are each selectively provided in the active region 10, between the front surface of the semiconductor substrate 40 and the p-type base region 4. The n⁺-type source regions 5 and the p⁺⁺-type contact regions 6 are in contact with the p-type base region 4 and are exposed at the front surface of the semiconductor substrate 40. The n⁺-type source regions 5 and the p⁺⁺-type contact regions 6 being exposed at the front surface of the semiconductor substrate 40 means that said regions are in contact with the later-described source electrode (first electrode) 18 at a later-described first portion 40a of the front surface of the semiconductor substrate 40.

The n⁺-type source regions 5 and the p⁺⁺-type contact regions 6 extend linearly, for example, in the second direction Y, between the gate trenches 7 that are adjacent to each other. The n⁺-type source regions 5 are disposed closer to the gate trenches 7 than are the p⁺⁺-type contact regions 6 and are in contact with the gate insulating films 8 at the sidewalls of the gate trenches. The p⁺⁺-type contact regions 6 may be omitted. In an instance in which the p⁺⁺-type contact regions 6 are omitted, instead of the p⁺⁺-type contact regions 6, the p-type base region 4 are exposed at the first portion 40a of the front surface of the semiconductor substrate 40.

The gate trenches 7 penetrate through the n⁺-type source regions 5 and the p-type base region 4 in the depth direction Z from the first portion 40a of the front surface of the semiconductor substrate 40 and reach the n-type column regions 31 (in an instance in which a later-described n-type current spreading region is provided, the n-type current spreading region). The gate trenches 7 extend in a striped pattern in the second direction Y. A length of each of the gate trenches 7 (length in the longitudinal direction) is set so that ends of the gate trenches 7 in a lateral direction of the gate trenches 7 terminate close to a border between the active region 10 and the edge termination region 20.

Thus, the lengths of the gate trenches 7 terminating at the corners of the active region 10 decrease stepwise the closer the gate trenches 7 are disposed to the chip end in the first direction X, corresponding to the curve of the corners of the active region 10 (FIGS. 5A to 7). The gate trenches 7 terminating at the corners of the active region 10 without another one of the gate trenches 7 adjacent thereto closer to the chip end in the first direction X constitute the outermost gate trenches 7a. The chip-end side of each of the outermost gate trenches 7a is free of the n⁺-type source regions 5. The gate electrodes 9 are provided in the gate trenches 7 via the gate insulating films 8.

Between the parallel pn layer 3 and the p-type base region 4 in the active region 10, the p⁺-type regions (second-conductivity-type high-concentration regions) 11, 12 are each selectively provided at deep positions closer to the n⁺-type drain region 1 (the back surface of the semiconductor substrate 30) than are bottoms of the gate trenches 7. The p⁺-type regions 11, 12 extend in a striped pattern in the second direction Y. In junction FET (JFET) portions between the p⁺-type regions 11, 12 adjacent to one another, the n-type column regions 31 (or the later-described n-type current spreading region) intervene so as to reach the p-type base region 4 from the n⁺-type drain region 1.

The p⁺-type regions 11, 12 are fixed to the potential of the source electrode 18, deplete when the MOSFET is in the off-state (or causes the JFET portions to deplete, or both), and have a function of mitigating electric field applied to the gate insulating films 8 at the bottoms of the gate trenches 7. The JFET portions are portions of the n-type column regions 31 (or the later-described n-type current spreading region) between the p⁺-type regions 11, 12 adjacent to one another, and adjacent to a channel formed on a current path of drift current that flows between a drain and source when the MOSFET is in the on-state.

The p⁺-type regions 12 are formed in surface regions of the n-type epitaxial layer 42. In particular, the p⁺-type regions 12 are diffused regions formed by lower portions (portions facing the n⁺-type drain region 1: first portions) 13 and upper portions (portions facing the n⁺-type source regions 5 (the front surface of the semiconductor substrate 40): second portions) 14 adjacent to one another in the depth direction Z and are formed by performing ion-implantation of a p-type impurity in each layer formed at each of the two stages (two sessions) into which epitaxial growth of the n-type epitaxial layer 42 constituting the drift layer (the parallel pn layer 3) is divided. The p⁺-type regions (first portions) 11 are formed concurrently with the lower portions 13 of the p⁺-type regions 12.

In particular, the p⁺-type regions 11 are apart from the p-type base region 4 and face the bottoms and bottom corner portions of the gate trenches 7 in the depth direction Z. The bottom corner portions of the gate trenches 7 are borders between the bottom and the sidewalls of the gate trenches 7. The p⁺-type regions 11 are adjacent to the n-type column regions 31 in the depth direction Z. The p⁺-type regions 11 may be in contact with the gate insulating films 8 at the bottoms of the gate trenches 7. A width of each of the p⁺-type regions 11 is set to be wider than a width of each of the gate trenches 7 by a predetermined width W11 from each of the sidewalls of the gate trenches 7 (both sidewalls in the lateral direction (the first direction X) and both ends in the longitudinal direction (the second direction Y)) (refer to FIGS. 4A1, 4A2).

The p⁺-type regions 11 directly beneath (side facing the n⁺-type drain region 1) the gate trenches 7 are all set to have the same width. Thus, in the second direction Y, the p⁺-type regions 11 terminate the predetermined width W11 from the ends of the gate trenches 7 in the longitudinal direction and are not in contact with the JTE structure 21. Outermost ones 11a of the p⁺-type regions 11 directly beneath the outermost gate trenches 7a, respectively, also terminate closer to the chip end than are the sidewalls of the gate trenches 7 by the width W11 in the first direction X and are not in contact with the JTE structure 21 (refer to FIGS. 3, 4A1, and 4A2).

The dimensions of each of the p⁺-type regions 11, for example, in both the lateral direction (the first direction X) and the longitudinal direction (the second direction Y), are greater than those of each of the gate trenches 7 by the width W11 from each of the sidewalls of the gate trenches 7 (both sidewalls in the lateral direction) and each of the ends of the gate trenches 7 (both ends in the longitudinal direction). In particular, for example, when a width W10 of each of the gate trenches 7 in a lateral direction is about 0.8 μm, the width of each of the p⁺-type regions 11 may be set to be wider, in the first direction X and in the second direction Y, by the width W11 of not more than about 0.35 μm from each of the sidewalls of the gate trenches 7 in the lateral direction and from each of the ends of the gate trenches 7 in the longitudinal direction.

As described, the p⁺-type regions 11, 11a extend slightly closer to the chip end than are outermost peripheral sidewalls of the gate trenches 7 (the outermost peripheral sidewalls being adjacent to the edge termination region 20) and the p⁺-type regions 11, 11a surround the borders between the bottom and the sidewalls (the bottom corner portions) of the gate trenches 7. The outermost peripheral sidewalls of the gate trenches 7 and adjacent to the edge termination region 20 are the respective outer sidewalls (those facing the chip end) of the outermost gate trenches 7a and sidewalls of the ends (in the longitudinal direction) of the gate trenches 7. The p⁺-type region 11a directly beneath the outermost gate trenches 7a surrounds the periphery of the active region 10 and in the active region 10, connects all the p⁺-type regions 11 and the lower portions 13 of the p⁺-type regions 12 provided closest to the n⁺-type drain region 1 in the depth direction Z.

As described, the p⁺-type regions 11, 11a and the lower portions 13 of the p⁺-type regions 12 terminate in a vicinity of the border between the edge termination region 20 and the active region 10 so as to surround borders between the bottom and the outermost peripheral sidewalls of the gate trenches 7 (the outermost peripheral sidewalls facing the edge termination region 20); and the edge termination region 20 is substantially free of the p⁺-type regions 11, 11a and the lower portions 13 of the p⁺-type regions 12. At the corners of the semiconductor substrate 40, an outer periphery 24c of the p⁺-type region 11a may be curved maintaining a predetermined distance with respect to the inner periphery 24a of the JTE structure 21 (refer to FIGS. 5A and 5B) or may have a stepped-shape maintaining a predetermined distance with respect to an outermost periphery of a cell (refer to FIGS. 6A and 6B).

The outer periphery 24c of the p⁺-type region 11a, in the linear portion of the semiconductor substrate 40, has a linear shape maintaining a predetermined distance with respect to the outermost periphery of a cell. The outermost periphery of a cell, in the active region 10, is a border between the edge termination region 20 and a unit cell disposed outermost among the multiple unit cells disposed adjacent to one another and is substantially a same as an outer periphery of the active region 10. Maintaining a predetermined distance with respect to the outermost periphery of a cell means being wider and maintaining the width W11 from the outermost peripheral sidewalls of the gate trenches 7 (the outermost peripheral sidewalls facing the edge termination region 20.

The outer periphery 24c of the p⁺-type region 11a has a curved shape maintaining a predetermined distance with respect to the inner periphery 24a of the JTE structure 21, whereby at the corners of the semiconductor substrate 40, the radius of curvature of the corners of the outer periphery 24c of the p⁺-type region 11a may be increased. As a result, while the MOSFET is in the off-state, near the corners of the outer periphery 24c of the p⁺-type region 11a, the concentration of electric field at the gate insulating films 8 at the bottoms of the gate trenches 7 is inhibited, whereby the breakdown voltage of the edge termination region 20 may be enhanced.

The outer periphery 24c of the p⁺-type region 11a has a stepped shape maintaining a predetermined distance along the outermost periphery of a cell, whereby between the inner periphery 24a of the JTE structure 21 and the outer periphery 24c of the p⁺-type region 11a, the number of the p-type column regions 32 in contact with the later-described p⁺-type extension portion 14a may be increased. As a result, in the edge termination region 20, the p-type column regions 32 whose length, in the depth direction Z, is longer than that of the p-type column regions 32 of the active region 10 increase and thus, an effect (enhancement of breakdown tolerance) of the later-described first embodiment may be further obtained.

Further, a width of each of the p⁺-type regions 11 in a lateral direction is narrower than a width Wn1 of each of the n-type column regions 31 in the lateral direction. The p⁺-type regions 11, for example, partially extend in a direction to the p⁺-type regions 12 or are connected to the p⁺-type regions 12 via other p⁺-type regions (hereinafter, p⁺-type connecting portions). FIGS. 5A, 5B, 6A, and 6B depict states in which the p⁺-type regions 11 and the lower portions 13 of the p⁺-type regions 12 are connected by the lower portions 15 of the p⁺-type connecting portions, thereby, forming a lattice-like shape. FIG. 7 depicts a state in which the upper portions 14 of the p⁺-type regions 12 and the upper portions 16 of the p⁺-type connecting portions are disposed so as to form a lattice-like shape.

The p⁺-type regions 12 are provided between the gate trenches 7 that are adjacent to one another, the p⁺-type regions 12 being in contact with the p-type base region 4 but apart from the p⁺-type regions 11 and the gate trenches 7. The p⁺-type regions 12 are adjacent to the p-type column regions 32 in the depth direction Z. A width of each of the p⁺-type regions 12 in the lateral direction is substantially a same as the width Wp1 of each of the p-type column regions 32 in the lateral direction, and the p⁺-type regions 12 may be in contact with the n-type column regions 31. The lower portions 13 of the p⁺-type regions 12 are formed by ion-implantation of a p-type impurity into the p-type column regions 32 and are provided overlapping the p-type column regions 32.

The lower portions 13 of the p⁺-type regions 12 overlap the p-type column regions 32, whereby the impurity concentration of the lower portions 13 of the p⁺-type regions 12 is higher than the impurity concentration of the upper portions 14 of the p⁺-type regions 12. As a result, when voltage (forward voltage) that is positive with respect to the source electrode 18 is applied to a drain electrode 19, the JFET portions between the p⁺-type regions 1 and the lower portions 13 of the p⁺-type regions 12 easily deplete. As a result, the time until a drain-source current is blocked is shortened and short-circuit capability may be enhanced.

Further, the lower portions 13 of the p⁺-type regions 12 overlap the p-type column regions 32, whereby when voltage that is positive with respect to the source electrode 18 is applied to the drain electrode 19, spreading of a depletion layer in the p-type column regions 32 is inhibited. Thus, as compared to an instance in which the lower portions 13 of the p⁺-type regions 12 do not overlap the p-type column regions 32, an effective length of the p-type column regions 32 in the depth direction Z is shortened. Thus, as compared to an instance in which the lower portions 13 of the p⁺-type regions 12 do not overlap the p-type column regions 32, the breakdown voltage of the active region 10 may be intentionally reduced.

Between the gate trenches 7 that are adjacent to one another, the n-type current spreading region (not depicted) may be provided between and in contact with the p⁺-type regions 11, 12, the p-type base region 4, and the n-type column regions 31, and may be provided so as to extend in the first direction X to reach the sidewalls of the gate trenches 7. The n-type current spreading region is a so-called current spreading layer (CSL) that reduces carrier spreading resistance. An impurity concentration of the n-type current spreading region is at least equal to the impurity concentration of the n-type column regions 31.

An interlayer insulating film 17 is provided in an entire area of the front surface of the semiconductor substrate 40 and covers the gate electrodes 9. The source electrode 18, in contact holes of the interlayer insulating film 17, is in ohmic contact with the first portion 40a of the front surface of the semiconductor substrate 40 and is electrically connected to the p-type base region 4, the n⁺-type source regions 5, and the p⁺⁺-type contact regions 6. The drain electrode (second electrode) 19 is provided in an entire area of the back surface (back surface of the n⁺-type starting substrate 41) of the semiconductor substrate 40 and is electrically connected to the n⁺-type drain region 1.

The p-type epitaxial layer 43 is removed in an outer portion of the edge termination region 20 and is left in a mesa-like shape (protruding shape) in a center of the front surface of the semiconductor substrate 40. The p-type epitaxial layer 43 is left in a mesa-like shape in the center of the front surface of the semiconductor substrate 40, whereby the incline 44 is formed at the front surface of the semiconductor substrate 40. Due to the incline 44, the front surface of the semiconductor substrate 40 has a second portion 40b that is recessed toward the drain electrode 19; the incline 44 is a border between the first portion 40a and the second portion 40b; and the second portion 40b is closer to the chip end than is the first portion 40a on the chip-center side of the incline 44.

The first portion 40a of the front surface of the semiconductor substrate 40 is a surface of the p-type epitaxial layer 43. The second portion 40b of the front surface of the semiconductor substrate 40 is a surface of the n-type epitaxial layer 42, which is exposed by removing the p-type epitaxial layer 43 in the outer portion of the edge termination region 20. The JTE structure 21 configured by multiple p-type regions of differing impurity concentrations is provided as a voltage withstand structure, between the second portion 40b of the front surface of the semiconductor substrate 40 and the parallel pn layer 3; the JTE structure 21 is provided closer to the chip end than is the incline 44.

The JTE structure 21 and the device of the active region 10 are separated by a third portion (mesa edge of the incline) 40c connecting the first portion 40a and the second portion 40b of the front surface of the semiconductor substrate 40. The JTE structure 21 is formed by disposing multiple p-type regions (second-conductivity-type voltage withstanding regions) of differing impurity concentrations in descending order of impurity concentration in a direction from the active region 10 to the chip end so as to surround the periphery of the active region 10 in adjacent concentric shapes. In FIG. 2, a double-zone JTE structure configured by two p-type regions (the p⁻-type region 22 and the p⁻⁻-type region 23) of differing impurity concentrations is depicted as the JTE structure 21.

Lower surfaces (surfaces facing the n⁺-type drain region 1) of the p-type regions (the p⁻-type region 22 and the p⁻⁻-type region 23) configuring the JTE structure 21 are at a depth closer to a depth of the n⁺-type source regions 5 than are lower surfaces of the p⁺-type regions 11 and lower surfaces of the lower portions 13 of the p⁺-type regions 12, and closer to the n⁺-type drain region 1 than are lower surfaces of the upper portions 14 of the p⁺-type regions 12 and a lower surface of the later-described p⁺-type extension portion 14a. Upper surfaces (surfaces facing the interlayer insulating film 17) of the p-type regions configuring the JTE structure 21 are at a depth closer to a depth of the n⁺-type source regions 5 than are the lower surfaces of the upper portions 14 of the p⁺-type regions 12 and the lower surface of the p⁺-type extension portion 14a.

The upper surfaces of the p-type regions configuring the JTE structure 21 are exposed at the second portion 40b of the front surface of the semiconductor substrate 40. The second and third portions 40b, 40c of the front surface of the semiconductor substrate 40 are covered by an insulating layer (the interlayer insulating film 17 having a single-layer structure or a stacked structure in which a field oxide film (not depicted) and the interlayer insulating film 17 are sequentially stacked). Being exposed at the second and third portions 40b, 40c of the front surface of the semiconductor substrate 40 means being in contact with the insulating layer on the second and third portions 40b, 40c of the front surface of the semiconductor substrate 40.

The parallel pn layer 3 is provided closer to the chip end than is the JTE structure 21. In the parallel pn layer 3, closest to the chip end in the first direction X is one of the p-type column regions 32. Between the end of the semiconductor substrate 40 and the parallel pn layer 3 is the normal n-type drift region 33 that is free of the SJ structure. An impurity concentration of the normal n-type drift region 33 is not more than the impurity concentration of the n-type column regions 31 of the parallel pn layer 3. The parallel pn layer 3 is exposed at the second portion 40b of the front surface of the semiconductor substrate 40, between the JTE structure 21 and the normal n-type drift region 33.

Between the front surface of the semiconductor substrate 40 and the normal n-type drift region 33, an n⁺-type channel stopper 25 is selectively provided apart from the parallel pn layer 3. The normal n-type drift region 33 and the n⁺-type channel stopper 25 are provided along an outer periphery of the semiconductor substrate 40 and surround a periphery of the parallel pn layer 3. The normal n-type drift region 33 and the n⁺-type channel stopper 25 are exposed at side surfaces of the semiconductor substrate 4. Instead of the n⁺-type channel stopper 25, a p⁺-type channel stopper may be provided.

In a portion of the edge termination region 20 closer to the chip center than is the incline 44, the p-type base extension portion 4a is provided between the first portion 40a of the front surface of the semiconductor substrate 40 and the parallel pn layer 3. Between the p-type base extension portion 4a and the parallel pn layer 3, the p⁺-type extension portion (the second-conductivity-type high-concentration region) 14a is provided in contact with the p-type base extension portion 4a and the parallel pn layer 3 (the n-type column regions 31 and the p-type column regions 32). The p⁺-type extension portion 14a and the p-type base extension portion 4a are extension portions of the upper portions 14 of the p⁺-type regions 12 and the p-type base region 4, respectively.

The p⁺-type extension portion 14a and the p-type base extension portion 4a reach the outermost gate trenches 7a in the first direction X and, in the second direction Y, reach all the ends of the gate trenches 7 in the longitudinal direction; the p⁺-type extension portion 14a and the p-type base extension portion 4a extend in a direction to the chip end and reach the third portion 40c of the front surface of the semiconductor substrate 40. The p⁺-type extension portion 14a and the p-type base extension portion 4a are provided in an entire area from the active region 10 to the incline 44 and surround the periphery of the active region 10 (FIG. 7). All the p⁺-type regions 12 are connected at the ends of the upper portions 14 of the p⁺-type regions 12 in the second direction Y, by the p⁺-type extension portion 14a.

A lower surface of the p⁺-type extension portion 14a is closer to the n⁺-type drain region 1 than is the second portion 40b of the front surface of the semiconductor substrate 40. The p⁺-type extension portion 14a extends closer to the chip end than is the incline 44 and is exposed at the second portion 40b of the front surface of the semiconductor substrate 40. The p⁺-type extension portion 14a overlaps an inner peripheral side of the p⁻-type region 22 that, in the JTE structure 21, is closest to the chip center (FIGS. 2, 6A and 6B). The JTE structure 21 is in contact with the p⁺-type extension portion 14a and is fixed to the potential of the source electrode 18 via the p⁺-type extension portion 14a and the p-type base extension portion 4a.

The p-type column regions 32 that are in the edge termination region 20 and closer to the chip center than is the JTE structure 21 are contact with the p⁺-type extension portion 14a and are fixed to the potential of the source electrode 18 via the p⁺-type extension portion 14a and the p-type base extension portion 4a. The p-type column regions 32 in contact with the JTE structure 21 are fixed to the potential of the source electrode 18 via the JTE structure 21. The p-type column regions 32 closer to the chip end than is the JTE structure 21 are exposed at the second portion 40b of the front surface of the semiconductor substrate 40. The p-type column regions 32 closer to the chip end than is the JTE structure 21 are electrically floating.

In the edge termination region 20, a lower surface of the p⁺-type extension portion 14a, lower surfaces of the p-type regions (the p⁻-type region 22 and the p⁻⁻-type region 23) configuring the JTE structure 21, and the second portion 40b of the front surface of the semiconductor substrate 40 are at a depth closer to the depth of the n⁺-type source regions 5 than are lower surfaces (lower surfaces of the lower portions 13 of the p⁺-type regions 12) of the p⁺-type regions 12 of the active region 10. Thus, a length (in the depth direction Z) of each of the p-type column regions 32 of the edge termination region 20 is greater than a length (in the depth direction Z) of each of the p-type column regions 32 of the active region 10.

The length (in the depth direction Z) of each of the p-type column regions 32 of the edge termination region 20 is greater than the length (in the depth direction Z) of each of the p-type column regions 32 of the active region 10, whereby the breakdown voltage of the edge termination region 20 is higher than the breakdown voltage of the active region 10. As a result, the SiC-MOSFET (the silicon carbide semiconductor device 50) may have a structure in which avalanche breakdown occurs in the active region 10, which has a large area occupying a majority of the area (surface area) of the semiconductor substrate 40. Thus, breakdown tolerance may be enhanced.

Instead of the JTE structure 21, a field limiting ring (FLR), which is a floating p-type region, may be provided. In this instance, the lower surface of the p⁺-type extension portion 14a and a lower surface of the FLR are at a depth closer to the depth of the n⁺-type source regions 5 than are lower surfaces of the lower portions 13 of the p⁺-type regions 12 and the p⁺-type regions 11, 11a of the active region 10, whereby the length (in the depth direction Z) of each of the p-type column regions 32 of the edge termination region 20 is longer than the length (in the depth direction Z) of each of the p-type column regions 32 of the active region 10 and the breakdown tolerance is enhanced.

The gate runner 45 (refer to FIG. 1) is provided between the active region 10 and the JTE structure 21. The gate runner 45, for example, includes a gate polysilicon wiring layer provided on the first portion 40a of the front surface of the semiconductor substrate 40 via a field oxide film (not depicted). The gate polysilicon wiring layer is covered by the interlayer insulating film 17. The gate polysilicon wiring layer is connected to all the gate electrodes 9 of the active region 10. The gate runner 45 electrically connects the gate electrodes 9 with a gate pad 46 (electrode pad, refer to FIG. 1).

Operation of the silicon carbide semiconductor device 50 according to the embodiment is described. When voltage (forward voltage) that is positive with respect to the source electrode 18 is applied to the drain electrode 19 and voltage at least equal to a gate threshold voltage is applied to the gate electrodes 9, a channel (n-type inversion layer) is formed in portions of the p-type base region 4 along the sidewalls of the gate trenches 7. As a result, a main current (the drift current) flows from the n⁺-type drain region 1, through the channels to the n⁺-type source regions 5 and the SiC-MOSFET (the silicon carbide semiconductor device 50) turns on.

On the other hand, when forward voltage is applied between the source and drain and voltage that is less than the gate threshold voltage is applied to the gate electrodes 9, pn junctions (main junctions of the active region 10) between the p⁺-type regions 11, 12, the p-type base region 4, and the n-type column regions 31 of the parallel pn layer 3 are reverse biased, whereby the main current stops flowing and the SiC-MOSFET maintains the off-state. The main junctions of the active region 10 (pn junctions) are reverse biased, whereby a depletion layer spreads from the pn junctions and a predetermined breakdown voltage of the active region 10 is sustained.

Further, while the SiC-MOSFET is in the off-state, the pn junctions between the p-type column regions 32 and the n-type column regions 31 are reverse biased and a depletion layer spreads from the pn junctions, whereby the breakdown voltage is born by the parallel pn layer 3. As a result, a predetermined breakdown voltage exceeding a breakdown voltage that can be realized by the impurity concentration (the n-type column regions 31) of the drift layer is sustained. Further, the length of the p-type column regions 32 in the depth direction Z is greater in the edge termination region 20 than that in the active region 10, whereby avalanche breakdown is facilitated in the active region 10.

A method of manufacturing the silicon carbide semiconductor device 50 according to the first embodiment is described. First, on the front surface of the n⁺-type starting substrate (semiconductor wafer) 41 constituting the n⁺-type drain region 1, the drift layer having the parallel pn layer 3 is formed. At this time, for example, using the multistage epitaxial method, the n-type epitaxial layer 42 constituting the drift layer is formed by epitaxial growth that is divided into multiple stages (sessions) and a p-type impurity such as aluminum (AI) is ion-implanted into each n-type epitaxial layer formed at each stage (session) of epitaxial growth, whereby portions constituting the p-type column regions 32 of the parallel pn layer 3 are selectively formed.

Portions of the n-type epitaxial layer 42 between the p-type column regions 32 that are adjacent to one another are free of ion implantation, remain an n-type, and constitute the n-type column regions 31 of the parallel pn layer 3. A portion of the n-type epitaxial layer 42 between the parallel pn layer 3 and the n⁺-type starting substrate 41 is entirely free of ion implantation and may be left as the n-type buffer region 2. Hereinafter, an instance in which the n-type buffer region 2 is provided is described as an example. A portion between the parallel pn layer 3 and the chip end (end of a portion constituting the semiconductor chip) free of ion implantation and left as an n-type constitutes the normal n-type drift region 33.

The n-type column regions 31 may be formed by ion implantation of an n-type impurity. In this instance, instead of the n-type epitaxial layer 42, a non-doped epitaxial layer or an n⁻ type epitaxial layer is formed by epitaxial growth divided into multiple stages. In this instance, ion implantation of an n-type impurity may be suitably performed for the n-type buffer region 2 and the normal n-type drift region 33 according to the impurity concentration. Thus, for example, the n-type buffer region 2 and the normal n-type drift region 33 of an impurity concentration lower than that of the n-type column regions 31 may be formed.

Next, by ion implantation of a p-type impurity, the p⁺-type regions 11 and the lower portions 13 of the p⁺-type regions 12 adjacent to the n-type column regions 31 of the parallel pn layer 3 and the p-type column regions 32 in the depth direction Z, respectively, are selectively formed in surface regions of the parallel pn layer 3. The lower portions 13 of the p⁺-type regions 12 are formed by ion implantation of a p-type impurity into surface regions of the p-type column regions 32, so as to overlap the p-type column regions 32. Further, concurrently with the p⁺-type regions 11, the lower portions 15 of the p⁺-type connecting portions of the p⁺-type regions 11 and the lower portions 13 of the p⁺-type regions 12 are selectively formed.

Further, by epitaxial growth, the thickness of the n-type epitaxial layer 42 is increased to a predetermined thickness. Next, by ion implantation of a p-type impurity, in the portion by which the thickness of the n-type epitaxial layer 42 is increased, the upper portions 14 of the p⁺-type regions 12 and the upper portions 16 of the p⁺-type connecting portions adjacent to the lower portions 13 of the p⁺-type regions 12 and the lower portions 15 of the p⁺-type connecting portions in the depth direction Z, respectively, are each selectively formed. Further, concurrently with the upper portions 14 of the p⁺-type regions 12, the p⁺-type extension portion 14a adjacent to the parallel pn layer 3 in the depth direction Z is formed in an inner peripheral portion 20a of the edge termination region 20.

Next, on the n-type epitaxial layer 42, the p-type epitaxial layer 43 constituting the p-type base region 4 is epitaxially grown. As a result, the semiconductor substrate (semiconductor wafer) 40 in which the epitaxial layers 42, 43 are sequentially stacked on the n⁺-type starting substrate 41 and in which the parallel pn layer 3 is in the n-type epitaxial layer 42 is fabricated. Next, in the outer portion of the edge termination region 20, the p-type epitaxial layer 43 (or also a surface region of the n-type epitaxial layer 42) is removed by etching, thereby, exposing the parallel pn layer 3 in the outer portion of the edge termination region 20.

As a result, the incline 44 is formed at the front surface of the semiconductor substrate 40 and the p-type epitaxial layer 43 is left in a mesa-like shape in the inner peripheral portion 20a of the edge termination region 20 and the active region 10. In the outer portion of the edge termination region 20, the parallel pn layer 3 is exposed at the newly formed second portion 40b of the front surface of the semiconductor substrate 40. The mesa edge (the third portion 40c) of the incline 44 of the front surface of the semiconductor substrate 40, for example, may form an obtuse angle (inclined surface) with respect to the second portion 40b of the front surface of the semiconductor substrate 40 or may form a substantially right angle (orthogonal plane) therewith.

Next, by ion implantation, in the semiconductor substrate 40, at the front surface thereof, the n⁺-type source regions 5, the p⁺⁺-type contact regions 6, the JTE structure 21 (the p⁻-type region 22, the p⁻⁻-type region 23), and the n⁺-type channel stopper 25 are each selectively formed. The n⁺-type source regions 5 and the p⁺⁺-type contact regions 6 are each selectively provided in surface regions of the p-type epitaxial layer 43. Concurrently with the p⁺⁺-type contact regions 6, a p⁺⁺-type outer contact region (not depicted) may be formed in the inner peripheral portion 20a of the edge termination region 20.

The JTE structure 21 and the n⁺-type channel stopper 25 are each selectively formed in surface regions of the parallel pn layer 3 exposed at the second portion 40b of the front surface of the semiconductor substrate 40. The JTE structure 21 is formed at a timing different from that of the p⁺-type regions 11, 12 and the p⁺-type extension portion 14a. The inner peripheral side of the p⁻-type region 22 that, in the JTE structure 21, is closest to the chip center is formed so as to overlap the p⁺-type extension portion 14a in a vicinity of the incline 44 of the front surface of the semiconductor substrate 40. The n⁺-type channel stopper 25 may be formed concurrently with the n⁺-type source regions 5. Portions of the p-type epitaxial layer 43 free of ion implantation and having the same impurity concentration as that during epitaxial growth constitutes the p-type base region 4 and the p-type base extension portion 4a.

Next, a heat treatment for activating the impurities ion-implanted in the epitaxial layers 42, 43 is performed. Next, the gate trenches 7 that penetrate through the n⁺-type source regions 5 and the p-type base region 4 from the front surface of the semiconductor substrate 40 and face the p⁺-type regions 11 are formed. Next, by a general method, the gate insulating films 8, the gate electrodes 9, the interlayer insulating film 17, the source electrode 18, and the drain electrode 19 are formed. Thereafter, the semiconductor wafer (the semiconductor substrate 40) is diced (cut) into individual chips, whereby the silicon carbide semiconductor device 50 depicted in FIGS. 1 to 7 is completed.

In the described method of manufacturing the silicon carbide semiconductor device 50 according to the first embodiment, instead of the multistage epitaxial method, the parallel pn layer 3 may be formed using a trench-embedding epitaxial method. In an instance of the trench-embedding epitaxial method, in the n-type epitaxial layer 42, trenches (SJ trenches) of a depth equivalent to the length of the p-type column regions 32 in the depth direction Z are formed, portions to constitute the n-type column regions 31 are left, and the SJ trenches are embedded with a p-type epitaxial layer constituting the p-type column regions 32, whereby the parallel pn layer 3 is formed.

As described, according to the first embodiment, the lower surface of the p⁺-type extension portion that is provided in the edge termination region and fixes the JTE structure to the potential of the source electrode is at a depth closer to that of the n⁺-type source regions than are the lower surfaces of the p⁺-type regions (the p⁺-type regions directly beneath the gate trenches) provided in the active region, at deep positions closest to the n⁺-type drain region. As a result, the length of the p-type column regions in the depth direction in the edge termination region is longer than the length of the p-type column regions in the depth direction in the active region and the breakdown voltage of the edge termination region is enhanced, whereby the breakdown voltage of the edge termination region may be made higher than the breakdown voltage of the active region. Accordingly, a location where avalanche breakdown occurs is the active region, which has a large area occupying a majority of the area (surface area) of the semiconductor substrate and breakdown tolerance may be enhanced.

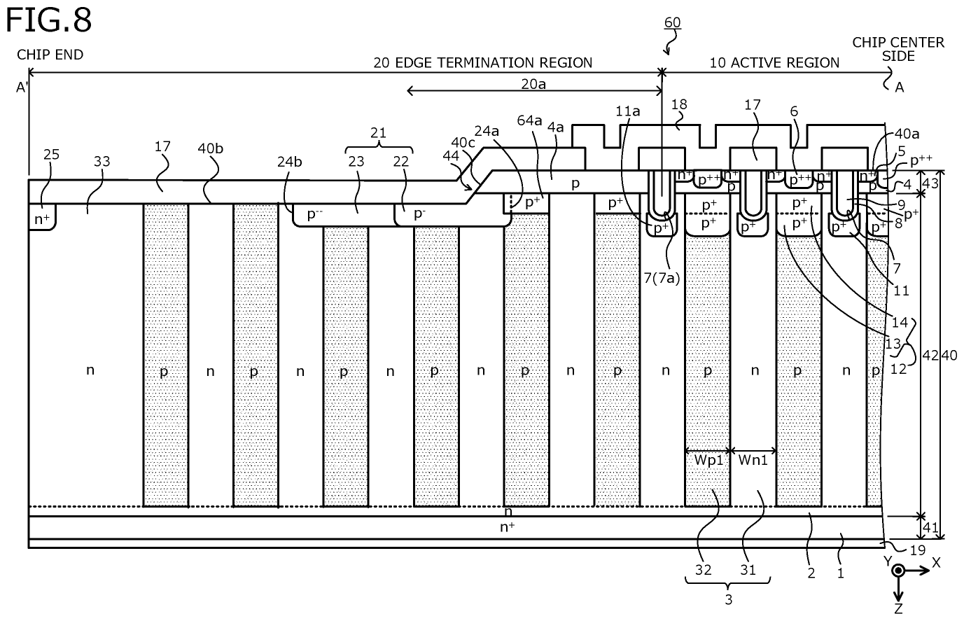

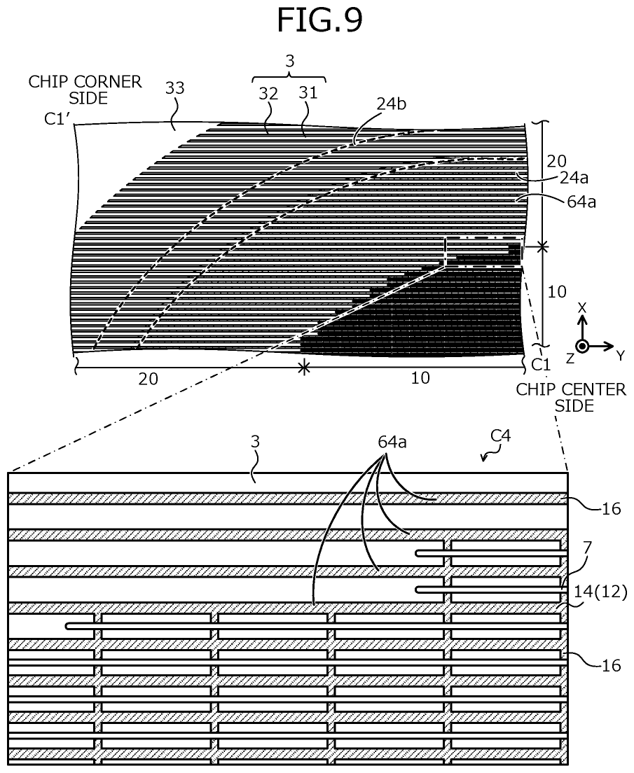

Next, a structure of a silicon carbide semiconductor device according to a second embodiment is described. FIG. 8 is a cross-sectional view depicting the structure of the silicon carbide semiconductor device according to the second embodiment. A layout when a silicon carbide semiconductor device 60 according to the second embodiment is viewed from the front surface of the semiconductor substrate 40 thereof is the same as that depicted in FIG. 1. FIG. 8 depicts a cross-section of the structure along cutting line A-A′ in FIG. 1. FIG. 9A is an enlarged plan view depicting a region inside a rectangular frame C1-C1′ in FIG. 1; FIG. 9B is an enlarged plan view depicting a region inside a rectangular frame C4 in FIG. 9A. FIGS. 9A and 9B depict a layout of p⁺-type extension portions 64a in the corners of the semiconductor substrate 40 in FIG. 8.

In FIG. 8, the p-type column regions 32 are indicated by hatching. In FIG. 8, a portion of the inner periphery 24a of the JTE structure 21 overlapping one of the p⁺-type extension portions 64a is indicated by a dashed line while the gate runner 45 is not depicted. In FIG. 8, the number of the n-type column regions 31 and the number of the p-type column regions 32 is simplified and differ from that in FIGS. 9.A and 9B. In FIG. 9A, the gate trenches 7 are indicated by bold lines while the inner periphery 24a and the outer periphery 24b of the JTE structure 21 are indicated by dashed lines. In FIGS. 9A and 9B, the upper portions 14 of the p⁺-type regions 12, the p⁺-type extension portions 64a, and the upper portions 16 of the p⁺-type connecting portions are indicated by the same hatching.

The silicon carbide semiconductor device 60 according to the second embodiment differs from the silicon carbide semiconductor device 50 according to the first embodiment (refer to FIGS. 2 and 7) in that the p⁺-type extension portions 64a are selectively provided in the inner peripheral portion 20a of the edge termination region 20. The p⁺-type extension portions 64a are extension portions of the upper portions 14 of the p⁺-type regions 12, formed concurrently with the upper portions 14 of the p⁺-type regions 12. For example, the layout may be such that the p⁺-type extension portions 64a are provided only between the p-type base extension portion 4a and the p-type column regions 32 and not between the p-type base extension portion 4a and the n-type column regions 31.

In this instance, between the p⁺-type extension portions 64a that are adjacent to one another, the n-type column regions 31 extend to the p-type base extension portion 4a. Thus, between the active region 10 and the incline 44, the length of the n-type column regions 31 in the depth direction Z is greater than the length of the p-type column regions 32 in the depth direction Z. A width of each of the p⁺-type extension portions 64a in a lateral direction thereof may less than the width Wp1 of each of the p-type column regions 32 in the lateral direction thereof (not depicted). Between the p-type base extension portion 4a and the p-type column regions 32, the p⁺-type extension portions 64a may extend linearly in the second direction Y (FIGS. 9A and 9B) or may be scattered in the second direction Y (not depicted).

In an instance in which the p⁺-type extension portions 64a extends linearly in the second direction Y, the ends of each of the p⁺-type extension portions 64a in the longitudinal direction (the second direction Y) thereof overlap the inner peripheral side of the p-type region 22 of the JTE structure 21. The ends of each of the p⁺-type extension portions 64a in the longitudinal direction thereof terminate closer to the chip center than are the ends of the p-type column regions 32 in the second direction Y. In an instance in which the p⁺-type extension portions 64a are scattered in the second direction Y, the p⁺-type extension portions 64a are provided in a matrix-like pattern between the active region 10 and the incline 44 when viewed from the front surface of the semiconductor substrate 30. Outermost ones of the p⁺-type extension portions 64a in the second direction Y overlap the inner peripheral side of the p⁻-type region 22 of the JTE structure 21. The outermost ones of the p⁺-type extension portions 64a in the second direction Y are positioned closer to the chip center than are the ends of the p-type column regions 32 in the second direction Y.

Regardless of the layout of the p⁺-type extension portions 64a, outermost ones of the p⁺-type extension portions 64a in the first direction X overlap the inner peripheral side of the p⁻-type region 22 that, in the JTE structure 21, is closest to the chip center (FIG. 8). The p⁺-type extension portions 64a adjacent to the outermost gate trenches 7a may be connected to the p⁺-type region 11a directly beneath the outermost gate trenches 7a by the upper portions 16 of the p⁺-type connecting portions and the lower portions 15 of the p⁺-type connecting portions (not depicted in FIGS. 8, 9A, and 9B). The outermost gate trenches 7a are the gate trenches 7 that are closest to the chip end in the first direction X and portions of the gate trenches 7 terminating in the corners of the active region 10, said portions being free of an adjacent one of the gate trenches 7 closer to the chip end in the first direction X.

A method of manufacturing the silicon carbide semiconductor device 60 according to the second embodiment may be implemented by changing the layout of the p⁺-type extension portions 64a in the method of manufacturing the silicon carbide semiconductor device 50 according to the first embodiment.

As described above, according to the second embodiment, in the inner peripheral portion of the edge termination region, the p⁺-type extension portion is provided only between the p-type base extension portion and the p-type column regions, whereby effects similar to those of the first embodiment may be obtained and said effects may be further enhanced.

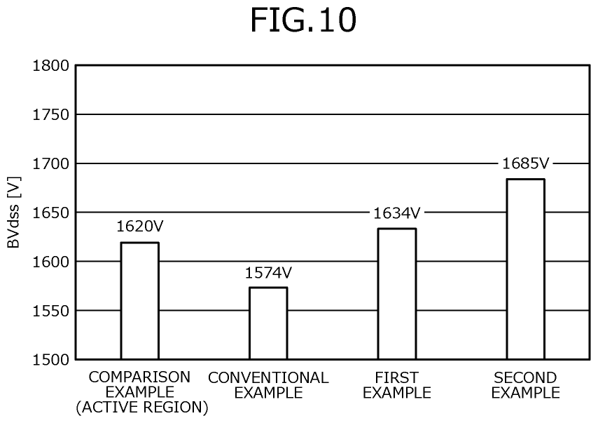

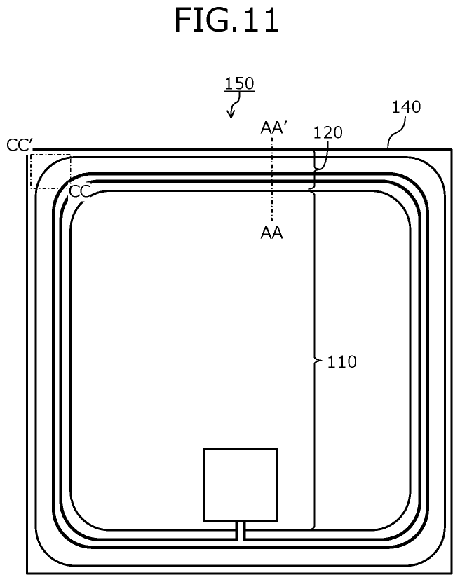

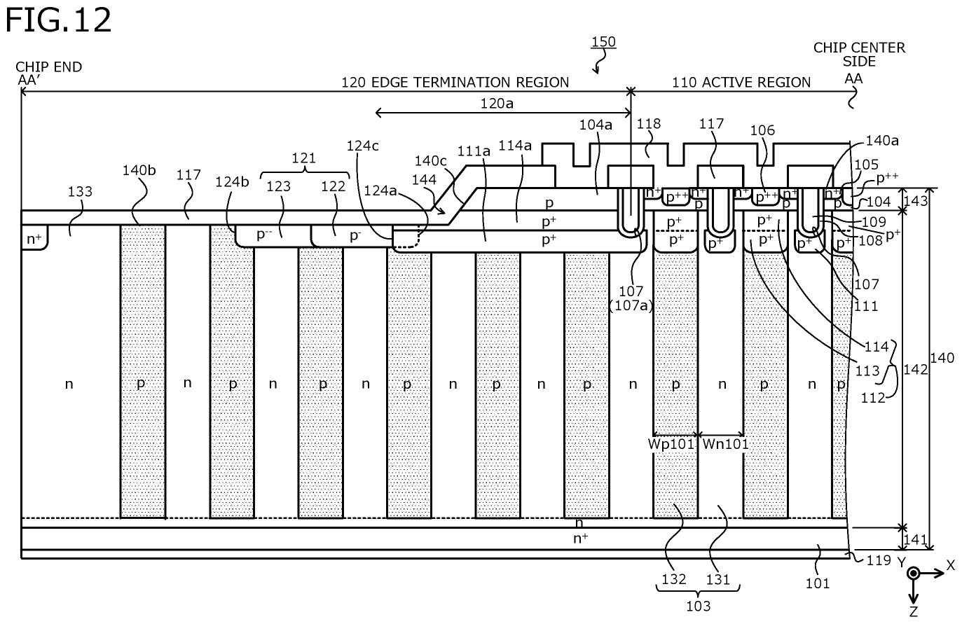

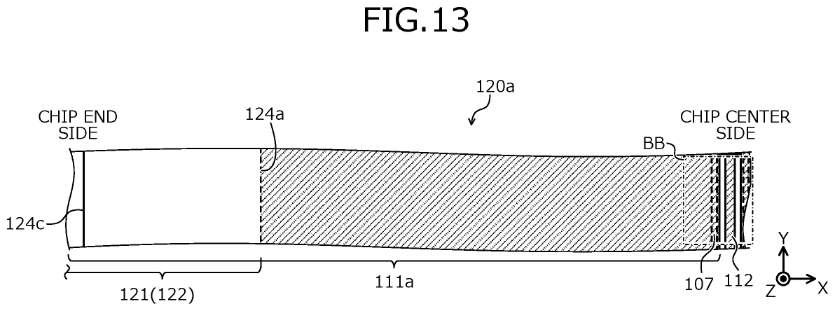

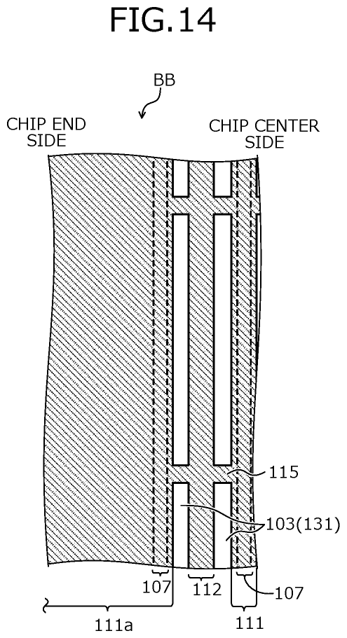

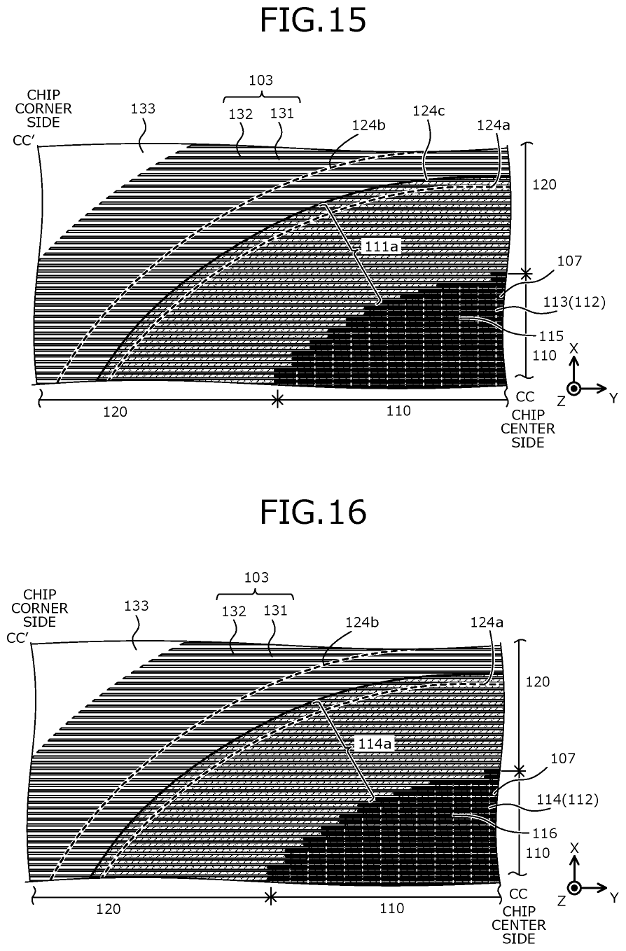

The breakdown voltage of the silicon carbide semiconductor devices 50, 60 according to the first and second embodiments described above was verified. FIG. 10 is a characteristics diagram depicting breakdown voltage characteristics of first and second examples. In FIG. 10, a horizontal axis indicates sample names (first and second examples, conventional example, and comparison example) while a vertical axis indicates breakdown voltage BVdss. Values on the bar graph are breakdown voltage values of each of the samples. Results of simulation of the breakdown voltage of the edge termination region 20 of the silicon carbide semiconductor devices 50, 60 according to the first and second embodiments (hereinafter, the first and second examples) and the breakdown voltage of the active region 10 (hereinafter, the comparison example) are depicted in FIG. 10.

For comparison, results of simulation of the breakdown voltage of the edge termination region 120 of the conventional silicon carbide semiconductor device 150 (hereinafter, conventional example) are also depicted in FIG. 10. The conventional example differs from the first and second examples in that in the inner peripheral portion 120a of the edge termination region 120, borders between the p-type column regions 132 and the p⁺-type extension portion 111a provided in contact with the JTE structure 121 are at a same depth as that of borders between the p-type column regions 132 and the p⁺-type regions 112 of the active region 110. The breakdown voltage of the active region 110 in the conventional example is a same as the breakdown voltage of the active region 10 in the first and second examples.

From the results depicted in FIG. 10, it was confirmed that in the conventional example, the breakdown voltage of the edge termination region 120 is lower than the breakdown voltage of the active region 110. On the other hand, it was confirmed that in the first and second examples, the breakdown voltage of the edge termination region 20 could be made higher than the breakdown voltage of the active region 10. Further, it was confirmed that in the second example, as compared to the first example, the breakdown voltage of the edge termination region 20 could be increased about 50V.

Thus, it was confirmed that like the first and second examples, in the edge termination region 20, the depth of the bottom of the p⁺-type extension portion 14a that fixes the JTE structure 21 to the potential of the source electrode 18 is shallow close to that of the n⁺-type source regions 5 and the length (in the depth direction Z) of each of the p-type column regions 32 of the edge termination region 20 is longer than the length (in the depth direction Z) of each of the p-type column regions 32 of the active region 10, whereby the breakdown voltage of the edge termination region 20 may be enhanced.

Further, it was confirmed that like the second example, the p⁺-type extension portions 64a that fix the JTE structure 21, in the edge termination region 20, to the potential of the source electrode 18 are provided only between the p-type base extension portion 4a and the p-type column regions 32 of the parallel pn layer 3, whereby as compared to an instance in which the p⁺-type extension portion 14a that fixes the JTE structure 21 to the potential of the source electrode 18 is provided in an entire area of the inner peripheral portion 20a of the edge termination region 20, the breakdown voltage of the edge termination region 20 may be further increased.

In the foregoing, the present invention is not limited to the described embodiments and may be variously modified within a range not departing from the spirit of the invention. For example, the length of the p-type column regions in the depth direction in the edge termination region suffice to be longer than the length of the p-type column regions in the depth direction in the active region, thereby making the breakdown voltage of the edge termination region higher than the breakdown voltage of the active region, and the lower portions of the p⁺-type regions between the gate trenches that are adjacent to one another need not overlap the p-type column regions of the parallel pn layer. Further, the present invention is not limited to a MOSFET and is applicable to silicon carbide semiconductor devices with a SJ structure with various configurations in which the drift layer is constituted by the parallel pn layer. Further, while in the described embodiments, the first conductivity type is assumed to be an n-type and the second conductivity type is assumed to be a p-type, the present invention is similarly implemented when the first conductivity type is a p-type and the second conductivity type is an n-type.

### INDUSTRIAL APPLICABILITY

As described, the silicon carbide semiconductor device according to the present invention is useful for power semiconductor devices used in power converting equipment, power source devices of various types of industrial machines, etc.

### EXPLANATIONS OF LETTERS OR NUMERALS

1 n⁺-type drain region

2 n-type buffer region

3 parallel pn layer

4 p-type base region

4a p-type base extension portion

5 n⁺-type source region

6 p⁺⁺-type contact region

7 gate trench

7a outermost gate trench

8 gate insulating film

9 gate electrode

10 active region

11 p⁺-type region for mitigating electric field directly beneath gate trench

11a p⁺-type region for mitigating electric field directly beneath outermost gate trench

12 p⁺-type region for mitigating electric field between adjacent gate trenches

13 lower portion of p⁺-type region for mitigating electric field between adjacent gate trenches

14 upper portion of p⁺-type region for mitigating electric field between adjacent gate trenches

14a, 64a p⁺-type extension portion

15 lower portion of p⁺-type connecting portion

16 upper portion of p⁺-type connecting portion

17 interlayer insulating film

18 source electrode

19 drain electrode

20 edge termination region

20a inner peripheral portion of edge termination region

21 JTE structure

22 p⁻-type region of JTE structure

23 p⁻⁻-type region of JTE structure

24a inner periphery of JTE structure

24b outer periphery of JTE structure

24c outer periphery of p⁺-type region for mitigating electric field directly beneath outermost gate trench

25 n⁺-type channel stopper region

31 n-type column region

32 p-type column region

33 normal n-type drift region

40 semiconductor substrate

40a to 40c front surface of semiconductor substrate

41 n⁺-type starting substrate

42 n-type epitaxial layer

43 p-type epitaxial layer

44 incline of front surface of semiconductor substrate

45 gate runner

46 gate pad

50, 60 silicon carbide semiconductor device

Wn1 width of n-type column region in lateral direction

Wp1 width of p-type column region in lateral direction

X first direction parallel to front surface of semiconductor substrate

Y second direction parallel to front surface of semiconductor substrate and orthogonal to first direction

Z depth direction

1. A silicon carbide semiconductor device, comprising:
an active region provided on a semiconductor substrate containing silicon carbide, the semiconductor substrate having a first main surface and a second main surface opposite to each other;
a termination region surrounding a periphery of the active region;
a parallel pn layer provided in the semiconductor substrate, spanning the active region and the termination region, the parallel pn layer having a plurality of first-conductivity-type column regions and a plurality of second-conductivity-type column regions disposed repeatedly alternating with one another in a first direction parallel to the first main surface of the semiconductor substrate;
a first semiconductor region of a second conductivity type, provided between the first main surface and the parallel pn layer, the first semiconductor region extending from the active region to the termination region;
a plurality of second semiconductor regions of a first conductivity type, selectively provided in the active region, between the first main surface and the first semiconductor region;
a plurality of trenches penetrating through the plurality of second semiconductor regions and the first semiconductor region in a depth direction of the device and reaching the plurality of first-conductivity-type column regions;
a plurality of gate electrodes provided in the plurality of trenches via a plurality of gate insulating films;
a second-conductivity-type high-concentration region selectively provided between the first semiconductor region and the parallel pn layer, the second-conductivity-type high-concentration region including a first part in the active region and a second part in the termination region, the second-conductivity-type high-concentration region having an impurity concentration higher than an impurity concentration of the plurality of second semiconductor regions;
a voltage withstand structure closer to an end of the semiconductor substrate than are the first semiconductor region and the second-conductivity-type high-concentration region, the voltage withstand structure being selectively provided between the first main surface and the parallel pn layer, and configured by one or more second-conductivity-type voltage withstanding regions surrounding a periphery of the active region in concentric shapes;
a first electrode electrically connected to the plurality of second semiconductor regions, the first semiconductor region, and the second-conductivity-type high-concentration region; and
a second electrode electrically connected to the second main surface of the semiconductor substrate, wherein
of the second-conductivity-type high-concentration region:
the first part in the active region reaches a position closer to the second main surface than are bottoms of the plurality of trenches, and
the second part in the termination region has a lower surface facing the second main surface, the lower surface being closer to the first main surface than is a lower surface of the first part in the active region.

2. The silicon carbide semiconductor device according to claim 1, wherein
the first part of the second-conductivity-type high-concentration region in the active region has:
a first portion closer to the second main surface than are the bottoms of the plurality of trenches, and
a second portion closer to the first main surface than are the bottoms of the plurality of trenches, and
the second part of the second-conductivity-type high-concentration region in the termination region is formed by the second portion extending in the termination region.

3. The silicon carbide semiconductor device according to claim 2, wherein
the first portion of the first part of the second-conductivity-type high-concentration region surrounds the periphery of the active region and maintains a predetermined distance relative to outermost peripheral sidewalls of the plurality of trenches, the outermost peripheral sidewalls being adjacent to the termination region.

4. The silicon carbide semiconductor device according to claim 2, wherein
the first portion of the first part of the second-conductivity-type high-concentration region terminates closer to the end of the semiconductor substrate than are outermost peripheral sidewalls of the plurality of trenches by not more than 0.35 μm, the outermost peripheral sidewalls being adjacent to the termination region.

5. The silicon carbide semiconductor device according to claim 2, wherein
the first portion of the first part of the second-conductivity-type high-concentration region surrounds the periphery of the active region and maintains a predetermined distance relative to an inner periphery of the voltage withstand structure.

6. The silicon carbide semiconductor device according to claim 1, wherein
the second part of the second-conductivity-type high-concentration region is provided in an entire area between the active region and the voltage withstand structure.

7. The silicon carbide semiconductor device according to claim 1, wherein
the second part of the second-conductivity-type high-concentration region is selectively provided in plural.

8. The silicon carbide semiconductor device according to claim 7, wherein
the second part of the second-conductivity-type high-concentration region in the termination region is provided only between the first semiconductor region and the plurality of second-conductivity-type column regions.

9. The silicon carbide semiconductor device according to claim 8, wherein
the plurality of first-conductivity-type column regions and the plurality of second-conductivity-type column regions extend in a stripe pattern in a second direction parallel to the first main surface of the semiconductor substrate and orthogonal to the first direction, and
the second part of the second-conductivity-type high-concentration region extends linearly in the second direction.

10. The silicon carbide semiconductor device according to claim 8, wherein
the plurality of first-conductivity-type column regions and the plurality of second-conductivity-type column regions extend in a stripe pattern in a second direction parallel to the first main surface of the semiconductor substrate and orthogonal to the first direction, and
the second part of the second-conductivity-type high-concentration region is scattered in the second direction so as to be disposed in a matrix-like pattern between the active region and the voltage withstand structure.

11. The silicon carbide semiconductor device according to claim 7, wherein
the second part of the second-conductivity-type high-concentration region has a width in the first direction narrower than a width of each of the plurality of second-conductivity-type column regions in the first direction.
